(19) United States
(12) Patent Application Publication
(10) Pub. No.: US 2008/0113213 A1
(43) Pub. Date: May 15, 2008

(54) Optical Amplifying Materials

(75) Inventors: Robert Beer, Marly (CH); Rolf Steiger, Praroman - Le Mouret (CH); Michel Schar, Grandson (CH); Libero Zuppiroli, Bonvillars (CH)

Correspondence Address: ONOFRIO LAW, 107 SHAD ROW, PIERMONT, NY, 10968, US

(73) Assignee: ILFORD IMAGING SWITZERLAND GMBH, Marly 1 (CH)

(21) Appl. No.: 10/561,134

(22) PCT Filed: Jun. 22, 2004
(86) PCT No.: PCT/EP04/06711

§ 371 Date: May 19, 2006

(30) Foreign Application Priority Data
Jun. 26, 2003 (EP) 03405471.8

(51) Int. Cl. B32B 9/00

(52) U.S. Cl. 428/690; 428/702

(57) ABSTRACT

An optical amplifying material is described, consisting of a support and having coated thereon a thin, transparent amplifying layer containing nanocrystalline, nanoporous aluminum oxides and/or aluminum oxide/hydroxides and, optionally, a binder, and, superposed on this layer, a luminescence layer preferably consisting of tris(8-hydroxyquinoline) aluminum.

### FIELD OF INVENTION

The invention relates to an optical amplifying material consisting of a support and having coated thereon a thin, transparent amplifying layer containing nanocrystalline, nanoporous aluminum oxides or aluminum oxide/hydroxides and, optionally, a binder, and, superposed on this layer, a luminescence layer preferably consisting of tris(8-hydroxyquinoline) aluminum.

### BACKGROUND OF THE INVENTION

Aerogels may be used for the preparation of optical amplifying layers having a low index of refraction. The emission of light by light emitting, luminescent systems is considerably increased by these layers, as described for example by A. Köhler, J. S. Wilson and R. H. Friend in “Fluorescence and Phosphorescence in Organic Materials”, Advanced Materials 14, 701-707 (2002). SiO₂ aerogels are suitable aerogels for such amplifying layers.

The preparation and the physical properties of these SiO₂ aerogels are described for example by T. Tsutsui, M. Yahiro, H. Yokogawa, K. Kawano and M. Yokoyama in “Doubling Coupling-Out Efficiency in Organic Light-Emitting Devices Using a Thin Silica Aerogel Layer”, Advanced Materials 13, 1149-1152 (2001). The preparation method for these SiO₂ aerogels is, however, complicated and time consuming. Furthermore, the surface of these SiO₂ aerogels has to be made hydrophobic in order to assure their long time stability, as described for example by Matsushita Electric Works Ltd. in patent applications EP 0,585,456, EP 0,653,377, EP 0,849,220 and EP 1,153,739.

The preparation of SiO₂ layers containing thermally decomposable polymers having a refractive index between 1.10 and 1.40 on a glass substrate by spin coating is described for example in patent U.S. Pat. No. 6,204,202.

Such polymer containing coating compositions have to be heated for 10 to 60 minutes at a temperature of at least 400° C. in order to decompose the polymer and to obtain pure SiO₂ layers having the required amplifying properties. Without the removal of the polymer during this high temperature treatment, the layers do not increase the emission of light.

OLED's (Organic light-emitting devices) on a glass substrate having a SiO₂ under layer are described by M.-H. Lu, M. S. Weaver, T. X. Zhou, M. Tothman, R. C. Kwong, M. Hack and J. J. Brown in “High-Efficiency Top-Emitting Organic Light-Emitting Devices”, Applied Physics Letters 81, 3921-3923 (2002). The presence of this SiO₂ under layer increases the emission of photons in a cone angle of 120° with respect to the plane of observation by 21% in comparison to a system without this under layer. The preparation of the SiO₂ layers as described herein is also cumbersome and uses a similar method as the one described by Matsushita Electric Works Ltd.

The use of such layers as optical amplifying layers for light emitting, luminescent systems (as for example OLED's) has the advantage that the increased light emission allows the reduction of applied voltages and electrical currents. Thereby the lifetime of such light emitting organic systems is considerably increased, because it is well known that lifetime is inversely proportional to the square of the applied voltage.

Compounds showing blue electroluminescence with high quantum yield are quite rare as shown in the compilation by Y. Li, M. K. Fung, Z. Xie, S.-T. Lee, L.-S. Hung and J. Shi in “An Efficient Pure Blue Light-Emitting Device with Low Driving Voltages”, Advanced Materials 14, 1317-1321 (2002). The preparation of these compounds is in most cases, however, complicated and possible only at temperatures of about 400° C.

The preparation of a new compound showing blue luminescence and electroluminescence at a temperature of 390° C., starting from tris(8-hydroxyquinoline) aluminum, was described for the first time by M. Cölle, J. Gmeiner, W. Milius, H. Hillebrecht and W. Brütting in “Preparation and Characterization of Blue-Luminescent Tris(8-hydroxy quinoline) aluminium (Alq₃)”, Advanced Functional Materials 13, 108-112 (2003). After a treatment of tris(8-hydroxyquinoline) aluminum for several hours at this temperature, crystals having a new crystal structure and showing blue luminescence and electroluminescence were obtained.

All these known methods for the preparation of SiO₂ amplifying layers are cumbersome and require high temperatures. For this reason, cost effective manufacturing is not possible. Supports consisting of cheap materials cannot be used due to the high temperatures, even in the case where the materials mentioned above would have the required properties also on relatively cheap plastic or paper supports.

The required high temperatures have the further disadvantage that temperature sensitive compounds, in particular organic compounds such as sensitizing dyes, wetting agents and the like, may not be incorporated. Furthermore, it is very difficult to prepare thin, flexible and non-brittle aerogel films of high stability showing good adhesion to the support by the sol-gel-method.

### SUMMARY OF THE INVENTION

We have now found amplifying layers for optical amplifying materials, which may be manufactured on cheap supports in a cost effective way without a high temperature treatment.

It is an objective of the invention to provide optical amplifying materials on cheap supports, having coated thereon at least one thin, transparent amplifying layer of high mechanical stability consisting of nanocrystalline, nanoporous aluminum oxides and/or aluminum oxide/hydroxides and, optionally, a binder, and having deposited a luminescence layer on this amplifying layer. These materials have a high optical amplification factor even without a high temperature treatment.

These transparent amplifying layers consisting of nanocrystalline, nanoporous aluminum oxides and/or aluminum oxide/hydroxides and, optionally, a binder, are catalysts for the transformation, at room temperature, of the crystal modification of tris(8-hydroxyquinoline) aluminum (Alq₃) showing green luminescence to the crystal modification showing blue luminescence.

Cheap supports for the present invention are glass, coated or uncoated paper, or plastic films.

Such a material has, coated onto the support, at least one least one amplifying layer consisting of nanocrystalline, nanoporous aluminum oxides and/or aluminum oxide/hydroxides and, optionally, a binder, and, on top of this layer, a luminescence layer consisting preferably of Alq₃ with the crystal modification showing blue or green luminescence.

The material may have one or more additional layers of other functionality between the amplifying layer and the luminescence layer, for example a layer of indium tin oxide for increased conductivity and lower surface roughness or a layer for increased mechanical robustness.

The thin, transparent amplifying layer consisting of nanocrystalline, nanoporous aluminum oxides and/or aluminum oxide/hydroxides and, optionally, a binder, is prepared by coating aqueous, colloidal dispersions consisting of nanocrystalline, nanoporous aluminum oxides and/or aluminum oxide/hydroxides and, optionally, a binder, at temperatures between 20° C. and 55° C. onto a glass substrate, onto a paper or a plastic support, optionally pre-coated with a tin indium oxide or metal layer. Afterwards, it is dried in a gas mixture, preferably in air, at a temperature below 100° C., preferably below 60° C.

Nanocrystalline, nanoporous aluminum oxides and aluminum oxide/hydroxides or aluminum oxides and aluminum oxide/hydroxides (AlOOH) doped with elements of the rare earth metal series of the periodic system of the elements, and γ-Al₂O₃, or their mixtures, are preferred.

### DETAILED DESCRIPTION OF THE INVENTION

It is an objective of the invention to provide optical amplifying materials on cheap supports, having coated thereon at least one thin transparent amplifying layer of high mechanical stability consisting of nanocrystalline, nanoporous aluminum oxides and/or aluminum oxide/hydroxides and, optionally, a binder, and having deposited a luminescence layer on this amplifying layer. These materials have a high optical amplification factor even without a high temperature treatment.

These transparent amplifying layers consisting of nanocrystalline, nanoporous aluminum oxides and/or aluminum oxide/hydroxides and, optionally, a binder, are additionally catalysts for the transformation, at room temperature, of the crystal modification of tris(8-hydroxyquinoline) aluminum (Alq₃) showing green luminescence to the crystal modification showing blue luminescence. In this way, it is possible to prepare optical amplifying material with either green or blue luminescence from the same starting material.

In place of Alq₃ other light emitting, luminescent, i.e. fluorescent, phosphorescent or electroluminescent compounds such as luminescent polymers may be used in the luminescent layer. The luminescent layers have to be very thin in order to prevent as much as possible light conduction within the luminescent layer. The luminescence of the luminescent layer may be stimulated by light or by an electric field (electroluminescence).

Such a material consists of a support having coated thereon at least one amplifying layer consisting of nanocrystalline, nanoporous aluminum oxides and/or aluminum oxide/hydroxides and, optionally, a binder, and a luminescence layer on top of this layer. The material may have one or more additional layers of other functionality between the amplifying layer and the luminescence layer, for example a layer of indium tin oxide for increased conductivity and lower surface roughness or a thin protection layer for increased mechanical robustness.

In a particularly preferred embodiment of the invention, the thin, transparent amplifying layer consisting of nanocrystalline, nanoporous aluminum oxides and/or aluminum oxide/hydroxides does not contain any binder.

The thin, transparent amplifying layer consisting of nanocrystalline, nanoporous aluminum oxides and/or aluminum oxide/hydroxides and, optionally, a binder, is prepared by coating at temperatures between 20° C. and 55° C. aqueous, colloidal dispersions consisting of nanocrystalline, nanoporous aluminum oxides and/or aluminum oxide/hydroxides and, optionally, a binder, onto a glass substrate, onto a paper or a plastic support, optionally pre-coated with a tin indium oxide or metal layer. Afterwards, it is dried in a gas mixture, preferably in air, at a temperature below 100° C., preferably below 60° C.

In a preferred embodiment of the invention, aqueous, colloidal dispersions consisting of such nanocrystalline, nanoporous aluminum oxides and/or aluminum oxide/hydroxides not containing any binder are coated onto a glass substrate, onto a paper or a plastic support, optionally pre-coated with a tin indium oxide or metal layer, and dried in a gas mixture, preferably in air, at a temperature below 100° C., preferably below 60° C.

In a particularly preferred embodiment of the invention, the aqueous, colloidal dispersions consisting of such nanocrystalline, nanoporous aluminum oxides and/or aluminum oxide/hydroxides not containing any binder are coated, optionally in combination with other coating liquids, at temperatures between 20° C. and 55° C. onto a glass substrate, onto a paper or a plastic support, optionally precoated with a tin indium oxide or metal layer, and dried in a gas mixture, preferably in air, at a temperature below 100° C.,. preferably below 60° C. The layers may also be dried by infrared radiation or by electron beams, or drying in a gas mixture may be combined with drying by infrared radiation or electron beams.

A suitable nanocrystalline, nanoporous aluminum oxide is γ-Al₂O₃, and a suitable nanocrystalline, nanoporous aluminum oxide/hydroxide of formula AlOOH is pseudo-boehmite.

The nanocrystalline, nanoporous aluminum oxide/hydroxides are preferably prepared by a sol-gel-process in the complete absence of acids, as described for example in patent DE 3′823′895.

In a particularly preferred embodiment of the invention, the nanocrystalline, nanoporous aluminum oxides or aluminum oxide/hydroxides are reacted with salts of the rare earth metal series of the periodic system of the elements, as described for example in patent application EP 0′875′394. These nanocrystalline, nanoporous aluminum oxides or aluminum oxide/hydroxides contain one or more elements of the periodic system of the elements with atomic numbers 57 to 71, preferably in a quantity from 0.2 to 2.5 mole percent relative to Al₂O₃. Lanthanum is a preferred element of the rare earth metal series.

These nanocrystalline, nanoporous aluminum oxides or aluminum oxide/ hydroxides preferably have a size between 5 nm and 100 nm, particularly preferred are sizes between 10 nm and 60 nm. The preferably have a narrow size distribution (40%).

The nanocrystalline, nanoporous aluminum oxides or aluminum oxide/hydroxides have high pore volumes of >0.2 ml/g, as determined by the BET isotherm method described by S. Brunauer, P. H. Emmet and I. Teller in “Adsorption of Gases in Multimolecular Layers”, Journal of the American Chemical Society 60, 309-319 (1938).

The amplifying layers contain the nanocrystalline, nanoporous aluminum oxides and/or aluminum oxide/hydroxides in a quantity between 0.2 g/m² and 20 g/m², in particular between 1 g/m² and 10 g/m². These quantities correspond to a layer thickness between 0.1 μm and 20 μm, respectively between 1 μm and 10 μm in the dry state.

The quantity of the film forming bonder in the case where it is used should be as low as possible, but still sufficiently high in order to obtain stable, non-brittle layers with good adhesion to the support. Quantities of the film forming binder up to 20 percent by weight may be used relative to the total amount of the nanocrystalline, nanoporous aluminum oxides and/or aluminum oxide/hydroxides in the amplifying layer.

Particularly preferred are quantities up to 5 percent by weight relative to the total amount of the nanocrystalline, nanoporous aluminum oxides and/or aluminum oxide/hydroxides in the amplifying layer.

Suitable binders, in the case where they are used, are in general water-soluble, insulating polymers.

Particularly preferred are water-soluble, film forming, insulating polymers.

The water-soluble, nonconductive polymers include for example natural polymers or modified products thereof such as albumin, gelatin, casein, starch, gum arabicum, sodium or potassium alginate, hydroxyethyl cellulose, carboxymethyl cellulose, α-, β- or γ-cyclodextrine and the like. In the case where one of the water-soluble polymers is gelatin, all known types of gelatin may be used as for example acid pigskin or limed bone gelatin and acid or base hydrolyzed gelatins.

A preferred natural, nonconductive, film forming binder is gelatin in particular acid pigskin gelatin with high isoelectric point.

Synthetic, insulating binders may also be used. Included are for example polyvinyl alcohol, polyvinyl pyrrolidone, completely or partially saponified products of copolymers of vinyl acetate and other monomers; homopolymers or copolymers of unsaturated carboxylic acids such as (meth)acrylic acid, maleic acid, crotonic acid and the like; homopolymers or copolymers of sulfonated vinyl monomers such as vinylsulfonic acid, styrene sulfonic acid and the like, furthermore homopolymers or copolymers of vinyl monomers of (meth)acrylamide; homopolymers or copolymers of other monomers with ethylene oxide; polyurethanes and; polyacrylamides. Water-soluble nylon type polymers; polyesters; polyvinyl lactams; acrylamide polymers; substituted polyvinyl alcohol; polyvinyl acetals; polymers of alkyl and sulfoalkyl acrylates and methacrylates; hydrolyzed polyvinyl acetates; polyamides; polyvinyl pyridines; polyacrylic acid; copolymers with maleic anhydride; polyalkylene oxides; polyethylene glycols; methacrylamide copolymers and maleic acid copolymers or fluoro polymers such as polyvinylidene fluoride may also be used. All these polymers may also be used as mixtures.

Preferred synthetic, insulating, film forming binders are polyvinyl alcohol, polyvinylidene fluoride, polyethylene oxides, polyethylene glycols, block copolymers and polyacryl nitrites or mixtures thereof.

Polythiophene, polyanilines, polyacetylenes, poly(3,4-ethylene)dioxythiophene and polyphenylenvinylene may be used as conductive, film forming polymers. Block copolymers of conductive and insulating polymers may also be used.

Although water insoluble, conductive or insulating film forming polymers are not specifically claimed in this invention, water insoluble, conductive or insulating film forming polymers or block copolymers are nevertheless considered part of the system.

The polymers mentioned above having groups with the possibility to react with a cross-linking agent may be cross-linked or hardened to form essentially water insoluble layers. Such cross-linking bonds may be either covalent or ionic. Cross-linking or hardening of the layers allows for the modification of the physical properties of the layers, like for instance their liquid absorption capacity or their resistance against layer damage and brittleness.

The cross-linking agents or hardeners are selected depending on the type of the water-soluble polymers to be cross-linked.

Organic cross-linking agents and hardeners include for example aldehydes (such as formaldehyde, glyoxal or glutaraldehyde), N-methylol compounds (such as dimethylol urea or methylol dimethylhydantoin), dioxanes (such as 2,3-dihydroxydioxane), reactive vinyl compounds (such as 1,3,5-trisacrylolyl hexahydro-s-triazine or bis-(vinylsulfonyl)methyl ether), reactive halogen compounds (such as 2,4-dichloro-6-hydroxy-s-triazine); epoxides; aziridines; carbamoyl pyridinium compounds or mixtures of two or more of the above mentioned cross-linking agents.

Inorganic cross-linking agents or hardeners include for example chromium alum, aluminum alum, boric acid, zirconium compounds or titanocenes.

The layers may also contain reactive substances that cross-link the layers under the influence of ultraviolet light, electron beams, X-rays or heat.

Such materials consisting of a support having coated a protective layer for increased mechanical robustness or an electrically active layer above the amplifying layer consisting of nanocrystalline, nanoporous aluminum oxides and/or aluminum oxide/hydroxides, are preferably hardened with a cross-linking agent, which is adapted to the polymer of the protective layer in order to obtain an excellent mechanical robustness. The material may have one or more additional layers of other functionality between the amplifying layer and the luminescence layer, for example a layer of indium tin oxide for increased conductivity and lower surface roughness or a this protection layer for increased mechanical robustness. In the case where polyvinyl alcohol is used as binder, boric acid or borates are preferably used as cross-linking agents.

These polymers may be blended with water insoluble natural or synthetic high molecular weight compounds, particularly with acrylate latices or with styrene acrylate latices.

Glass is a suitable support for the materials according to the invention, as well as a wide variety of flexible supports used for example in the manufacture of photographic materials. For the manufacture of the materials described herein, all those supports used in the manufacture of photographic materials may be used, such as clear films made from cellulose esters such as cellulose triacetate, cellulose acetate, cellulose propionate or cellulose acetate/butyrate, polyesters such as polyethylene terephthalate or polyethylene naphthalate, polyamides, polycarbonates, polyimides, polyolefins, polyvinyl acetals, polyethers, polyvinyl chloride and polyvinylsulfones. Polyester film supports, and especially polyethylene terephthalate, such as Mylar®, manufactured by DuPont, or polyethylene naphthalate are preferred because of their excellent dimensional stability characteristics.

The usual opaque supports used in the manufacture of photographic materials may be used including for example baryta paper, polyolefin coated papers or voided polyester as for instance Mylar® manufactured by DuPont. Especially preferred are polyolefin coated papers or voided polyester. All these supports may also be coated with a conductive metal layer. Plastic supports or glass coated with highly conductive layers may also be used as supports for the material according to the invention. Preferred are plastic supports, coated with metals or indium tin oxide, or glass coated with indium tin oxide.

When such supports, in particular polyester, are used, a subbing layer is advantageously coated first to improve the adhesion of the layers to the support. Useful subbing layers for this purpose are well known in the photographic industry and include for example terpolymers of vinylidene chloride, acrylonitrile and acrylic acid or of vinylidene chloride, methyl acrylate and itaconic acid. In place of the use of a subbing layer, the surface of the support may be subjected to a corona-discharge treatment before the coating process in order to improve the adhesion of the layers to the support.

The optical amplifying layers according to the invention are in general coated from aqueous solutions or dispersions containing all necessary ingredients. In many cases, wetting agents are added to those coating solutions in order to improve the coating behavior and the evenness of the layers. Although not specifically claimed in this invention, wetting agents nevertheless form an important part of the invention.

Plasticizers such as for example glycerol may be added to the optical amplifying layer in order to reduce brittleness.

The coating solutions may be coated onto the support by any number of suitable procedures. Usual coating methods for flexible supports include for example dip coating, extrusion coating, air knife coating, doctor blade coating, cascade coating and curtain coating. Dip coating or spin coating may be used for coating glass supports.

The coating solutions may also be applied onto glass or flexible supports using spray techniques or by intaglio printing or offset printing.

The amplifying layers may be coated in combination with the other layers mentioned before in different coating passes. It is preferred, however, that they are coated simultaneously in one coating pass.

The coating speed is related to the used coating procedure and may vary within wide limits. Curtain coating with speeds between 30 m/min and 500 m/min is a preferred coating procedure for flexible supports.

A support coated with such an amplifying layer consisting of nanocrystalline, nanoporous aluminum oxides and/or aluminum oxide/hydroxides and, optionally, a binder, is a suitable substrate for another manufacturing step, wherein a luminescence layer is deposited onto the coated support, preferably by high vacuum thermal evaporation.

The luminescence layer preferably consists of tris(8-hydroxyquinoline) aluminum (Alq₃), in a preferred embodiment of the invention of the crystal modification of Alq₃ showing green luminescence.

By exposure to daylight (about 1000 cd/m²) at room temperature in the presence of air, the crystal modification of Alq₃ showing green luminescence may be converted in a simple way into the crystal modification of Alq₃ showing blue luminescence. This conversion is only possible in the case where the luminescence layer is in direct contact with the amplifying layer consisting of nanocrystalline, nanoporous aluminum oxides and/or aluminum oxide/hydroxides.

This method allows the preparation of optical amplifying materials showing green luminescence as well as blue luminescence from the same precursor compound. It is also possible to prepare, by a suitable image-wise exposure to light, an optical amplifying material showing green luminescence and blue luminescence side by side.

The present invention will be illustrated in more detail by the following examples without limiting the scope of the invention in any way.

### EXAMPLES

### Example 1

### Amplifying Layer

20 g of aluminum oxide/hydroxide of formula AlOOH, prepared in the absence of acid according to the method of example 1 of patent DE 3′823′895, were dispersed under vigorous mechanical stirring at a temperature of 40° C. in 76.5 g of aqueous lactic acid (1.3%). Afterwards, 0.16 g of an aqueous solution (50%) of glycerol and 3.33 g of an aqueous solution (3%) of the wetting agent Triton® X-100, available from Union Carbide Corporation, Danbury, USA, were added. Total weight was adjusted to 100 g with deionised water and the dispersion was exposed at a temperature of 40° C. to ultrasound for 3 minutes. 12 g/m² of this coating solution were coated onto a hydrophilic glass plate. The coated glass plate was then dried for 60 minutes at a temperature of 30° C.

### Luminescence Layer

A 100 nm thick layer of Alq₃, available from H. W. Sands Corporation Jupiter, USA, was then evaporated in high vacuum at a pressure below 10⁻⁶ mbar onto this optical amplifying layer. The temperature in the evaporating vessel was increased continuously by resistance heating, until the deposition rate was about 0.1 nm per second. After cooling of the whole evaporation device to room temperature and increase of the internal pressure to atmospheric pressure, the samples were transferred to light-tight glove boxes filled with ambient air and kept there until the start of testing.

### Comparative Example C-1

In comparative example C-1 the luminescence layer of Alq₃ of example 1 was evaporated directly onto the glass plate.

### Example 2

### Amplifying Layer

The coating solution of the amplifying layer of example 1 was coated onto a transparent polyethylene terephthalate support. The coated polyethylene terephthalate support was then dried for 60 minutes at a temperature of 30° C.

### Luminescence Layer

The luminescence layer was evaporated as described in example 1, but with a layer thickness of 300 nm.

### Comparative Example C-2

In comparative example C-2, the luminescence layer of Alq₃ of example 2 was evaporated directly onto the transparent polyethylene terephthalate support.

### Example 3

### Amplifying Layer

36.7 g of an aqueous dispersion (30%) of aluminum oxide γ-Al₂O₃ (Aero-disp W630, available from Degussa AG, Frankfurt am Main, Germany) were mixed under vigorous mechanical stirring at a temperature of 40° C. with 51.51 g of deionised water. Afterwards, 7.33 g of a solution of polyvinyl alcohol with a hydrolysis degree of 99.9% (6%, molecular weight 124′000-186′000, available from Aldrich, Buchs, Switzerland), 0.16 g of an aqueous solution (50%) of glycerol and 3.33 g of an aqueous solution (3%) of the wetting agent Triton® X-100 were added. Total weight was adjusted to 100 g with deionised water and the dispersion was exposed at a temperature of 40° C. to ultrasound for 3 minutes. The resulting coating solution containing 22 g of Aerodisp W630 was very stable. 10 g of an aqueous solution (10%) of boric acid were added and 12 g/m² of this coating solution were coated onto a hydrophilic glass plate. The coated glass plate was then dried for 60 minutes at a temperature of 30° C.

### Luminescence Layer

This layer is the same as in example 1.

### Example 4

### Luminescence Layer

The coating solution of the amplifying layer of example 3 was coated onto a transparent polyethylene terephthalate support. The coated polyethylene terephthalate support was then dried for 60 minutes at a temperature of 30° C.

### Luminescence Layer

This layer is the same as in example 2.

### Test

The optical amplification factor A was determined by measuring the fluorescence intensity with a fluorescence spectrograph FluoroMax3, available from Jobin Yvon Ltd., Stanford, Great Britain, at the emission maximum at 510 nm of Alq₃. The optical amplifying materials of the examples and of the comparative examples were placed onto a glass slide and illuminated with monochromatic light of wavelength 350 nm at an angle of 20°. The intensity of the fluorescence light was measured at an angle of 90° with respect to the direction of the incident excitation light. The selected angle of 20° for the incident excitation light eliminates scattered light and the incident light completely before it enters the aperture of the spectrograph. A material without amplifying layer was used as reference.

Other samples were measured were illuminated at room temperature in the presence of air with daylight with an intensity of about 1000 cd/m².

### Results

The amplification factors for the non-illuminated samples, determined as described above, are listed in Table 1.

TABLE 1

| | Thickness of the | Refraction index of | |
|---|---|---|---|
| Example | aluminum containing | the aluminum | Amplification |
| No | layer (nm) | containing layer | factor A |
| 1 | 2500 | 1.2 | 1.6 |
| C-1 | — | — | 1.0 |
| 2 | 2400 | 1.3 | 2.2 |
| C-2 | — | — | 1.0 |
| 3 | 3500 | 1.2 | 2.1 |
| 4 | 3300 | 1.3 | 1.8 |

A comparison of the amplification factors of Table 1 immediately shows that the presence of the amplifying layers in the materials according to our invention, containing nanocrystalline, nanoporous aluminum oxides and/or aluminum oxide/hydroxides, considerably increases the amount of fluorescence light. The amplification factors are similar to those of optical amplifying materials that are state of the art and contain SiO₂.

The samples of the optical amplifying materials according to the invention that were illuminated at room temperature in the presence of air with daylight showed blue luminescence of similar intensity as the green fluorescence of non-illuminated samples.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. Optical amplifying materials comprising a support, having coated thereon an amplifying layer and a luminescence layer above this layer, wherein said amplifying layer contains nanocrystalline, nanoporous aluminum oxide and/or aluminum oxide/hydroxide.

15. Optical amplifying materials according to claim 14, wherein said amplifying layer contains said nanocrystalline, nanoporous aluminum oxide and/or aluminum oxide/hydroxide in a quantity from 0.1 g/m² to 20 g/m².

16. Optical amplifying materials according to claim 14, wherein said amplifying layer contains said nanocrystalline, nanoporous aluminum oxide and/or aluminum oxide/hydroxide in a quantity from 1 g/m² to 10 g/m².

17. Optical amplifying materials according to claim 14, wherein said nanocrystalline, nanoporous aluminum oxide and/or aluminum oxide/hydroxide in said amplifying layer comprises one or more of the elements of the periodic system of the elements with atomic numbers 57 to 71 in an amount of from 0.2 to 2.5 mole percent relative to Al₂O₃.

18. Optical amplifying materials according to claim 14, wherein said amplifying layer contains up to 10% of a binder relative to the quantity of the nanocrystalline, nanoporous aluminum oxide and/or aluminum oxide/hydroxide.

19. Optical amplifying materials according to claim 18, wherein said binder is film forming.

20. Optical amplifying materials according to claim 19, wherein said binder is polyvinyl alcohol.

21. Optical amplifying materials according to claim 14, wherein said amplifying layer contains up to 5% of a binder relative to the quantity of said nanocrystalline, nanoporous aluminum oxide and/or aluminum oxide/hydroxide.

22. Optical amplifying materials according to claim 21, wherein said binder is film forming.

23. Optical amplifying materials according to claim 22, wherein said binder is polyvinyl alcohol.

24. Optical amplifying materials according to claim 14, wherein said luminescence layer consists of tris(8-hydroxyquinoline) aluminum.

25. Optical amplifying materials according to claim 24, wherein said luminescence layer consists of the crystal modification of tris(8-hydroxyquinoline) aluminum showing green luminescence.

26. Optical amplifying materials according to claim 12, wherein said crystal modification of tris(8-hydroxyquinoline) aluminum showing green luminescence in said luminescence layer is transformed to the crystal modification showing blue luminescence by illumination at room temperature in the presence of air with daylight.

27. Optical amplifying materials according to claim 14, wherein said support is coated or uncoated paper, plastic film or glass.

28. A support with an amplifying layer comprising nanocrystalline, nanoporous aluminum oxide and/or aluminum oxide/hydroxide.

29. A support according to claim 28, wherein said nanocrystalline, nanoporous aluminum oxide and/or aluminum oxide/hydroxide in said amplifying layer comprises one or more of the elements of the periodic system of the elements with atomic numbers 57 to 71 in an amount of from 0.2 to 2.5 mole percent relative to Al₂O₃.

30. A support according to claim 28, wherein said amplifying layer further comprises a binder.

31. A support according to claim 28, wherein a luminescence layer is deposited on top of said amplifying layer.

32. A support according to claim 31, wherein said luminescence layer consists of the crystal modification of tris(8-hydroxyquinoline) aluminum showing green luminescence.

33. A support according to claim 32, wherein said crystal modification of tris(8-hydroxyquinoline) aluminum showing green luminescence in said luminescence layer is transformed to the crystal modification showing blue luminescence by illumination at room temperature in the presence of air with daylight.
